(19) United States
(12) Patent Application Publication
(10) Pub. No.: US 2014/0210487 A1
(43) Pub. Date: Jul. 31, 2014

(54) ANTENNA DEVICE

(71) Applicant: PANASONIC CORPORATION, Osaka (JP)

(72) Inventors: Masahiro OHARA, Osaka (JP); Hirotaka ISHIHARA, Osaka (JP)

(73) Assignee: PANASONIC CORPORATION, Osaka (JP)

(21) Appl. No.: 14/165,383

(22) Filed: Jan. 27, 2014

(30) Foreign Application Priority Data
Jan. 28, 2013 (JP) 2013-012830

(51) Int. Cl. G01R 27/32

(52) U.S. Cl. CPC G01R 27/32
USPC 324/629

(57) ABSTRACT

An antenna device includes a sensor electrode having a capacitance configured to change upon an object approaching or contacting the sensor electrode, a sensor circuit electrically connected to the sensor electrode, an antenna section, and a substrate having the sensor circuit mounted thereon and having the sensor electrode fixed thereto. The sensor circuit is configured to detect the capacitance. The substrate is inserted into the antenna section. This antenna device allows components to be easily positioned during assembly.

### TECHNICAL FIELD

The present invention relates to an antenna device configured to be installed in a door of, e.g. a vehicle or a house to lock and unlock the door by a remote control.

### BACKGROUND ART

Antenna devices installed in a door of, e.g. a vehicle or a house to lock and unlock the door by a remote control has been widely marketed.

FIG. 8A and FIG. 8B are a top perspective view and a bottom perspective view of antenna device 20 disclosed in Japanese Patent Laid-Open Publication No. 2009-290454. FIG. 9 is a cross-sectional view of antenna device 20. Antenna device 20 includes antenna section 3 and capacitance sensor section 222 for detecting a change of a capacitance.

Capacitance sensor section 222 includes substrates 7A and 7B, mounting section 8 provided on an upper surface of substrate 7A, sensor electrodes 11A and 11B provided on an upper surface of substrate 7B, and auxiliary electrode 4 provided on a lower surface of substrate 7B. Sensor electrode 11A has a ring shape. Sensor electrode 11B having a square shape is provided at an inner side of the ring shape of sensor electrode 11A. Substrate 7A is placed on substrate 7B as to sandwich sensor electrodes 11A and 11B between substrates 7A and 7B. Electronic components connected to sensor electrodes 11A and 11B are provided on mounting section 8.

Antenna section 3 includes magnetic core 9 having a rectangular parallelepiped shape, and coil 10 wound around magnetic core 9. Capacitance sensor section 222 and antenna section 3 are connected in a longitudinal direction of magnetic core 9.

Antenna device 20 is placed in a door handle of the vehicle such that auxiliary electrode 4 is positioned in an inner side of the door handle.

An operation of antenna device 20 will be described below. When a user carrying a portable device touches the door handle, capacitance sensor section 222 detects the touch by the user based on a change in the capacitance, and transmits a request signal having a predetermined frequency via antenna section 3. When the portable device receives the request signal, the portable device transmits a response signal to the vehicle. When a controller of the vehicle receives the response signal via a receiving antenna, the controller unlocks the door in response to the response signal.

In conventional antenna device 20, antenna section 3 and capacitance sensor section 222 formed as separate units are arranged to be adjacent to each other. This may cause a variation of the positions of capacitance sensor section 222 and antenna section 3.

### SUMMARY

An antenna device includes a sensor electrode having a capacitance configured to change upon an object approaching or contacting the sensor electrode, a sensor circuit electrically connected to the sensor electrode, an antenna section, and a substrate having the sensor circuit mounted thereon and having the sensor electrode fixed thereto. The sensor circuit is configured to detect the capacitance. The substrate is inserted into the antenna section.

This antenna device allows components to be easily positioned during assembly.

### BRIEF DESCRIPTION OF DRAWINGS

FIG. 1 is a perspective view of an antenna device according to Exemplary Embodiment 1 of the present invention.

FIG. 2 is a cross-sectional view of the antenna device on line 2-2 shown in FIG. 1.

FIG. 3A is a perspective view of an antenna section of the antenna device according to Embodiment 1.

FIG. 3B is a perspective view of a sensor electrode of the antenna device according to Embodiment 1.

FIG. 3C is a perspective view of a substrate of the antenna device according to Embodiment 1.

FIG. 4 is a cross-sectional view of the antenna device according to Embodiment 1 installed in a door handle of a vehicle.

FIG. 5 is a perspective view of the antenna device according to Embodiment 1 installed in the door handle.

FIG. 6 is a perspective view of an antenna device according to Exemplary Embodiment 2 of the invention.

FIG. 7A is a perspective view of a sensor electrode of the antenna device according to Embodiment 2.

FIG. 7B is a perspective view of a substrate of the antenna device according to Embodiment 2.

FIG. 8A and FIG. 8B are a top perspective view and a bottom perspective view of a conventional antenna device, respectively.

FIG. 9 is a cross-sectional view of the conventional antenna device.

### DETAIL DESCRIPTION OF PREFERRED EMBODIMENTS

### Exemplary Embodiment 1

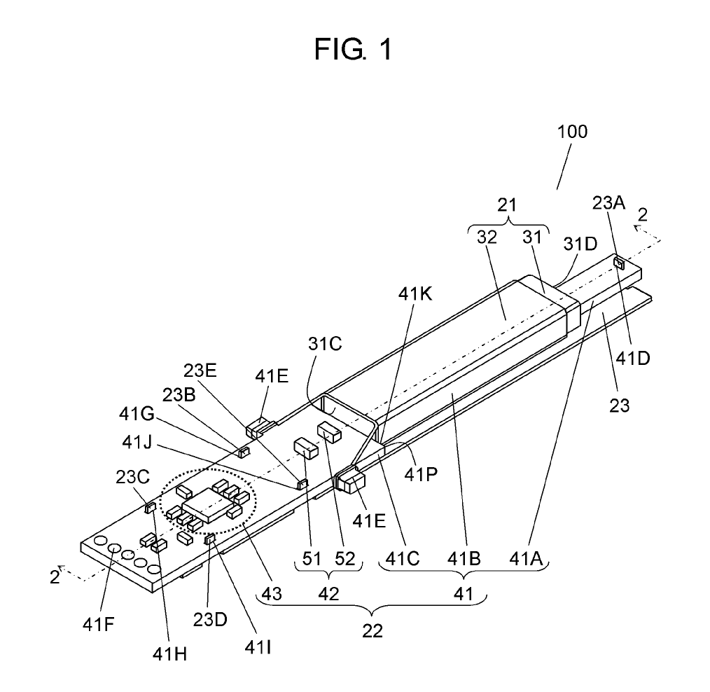

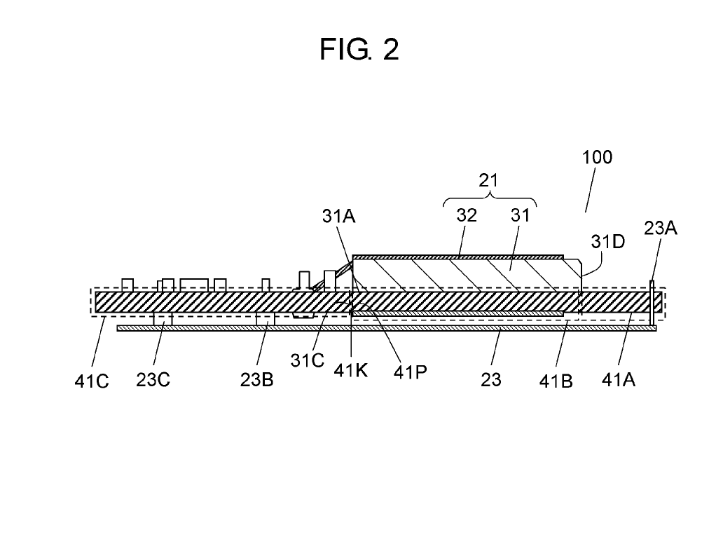

FIG. 1 is a perspective view of antenna device 100 according to Exemplary Embodiment 1 of the present invention. FIG. 2 is a cross-sectional view of antenna device 100 at line 2-2 shown in FIG. 1. Antenna device 100 includes antenna section 21, substrate unit 22, and sensor electrode 23. Antenna section 21 and sensor electrode 23 are both fixed to substrate unit 22.

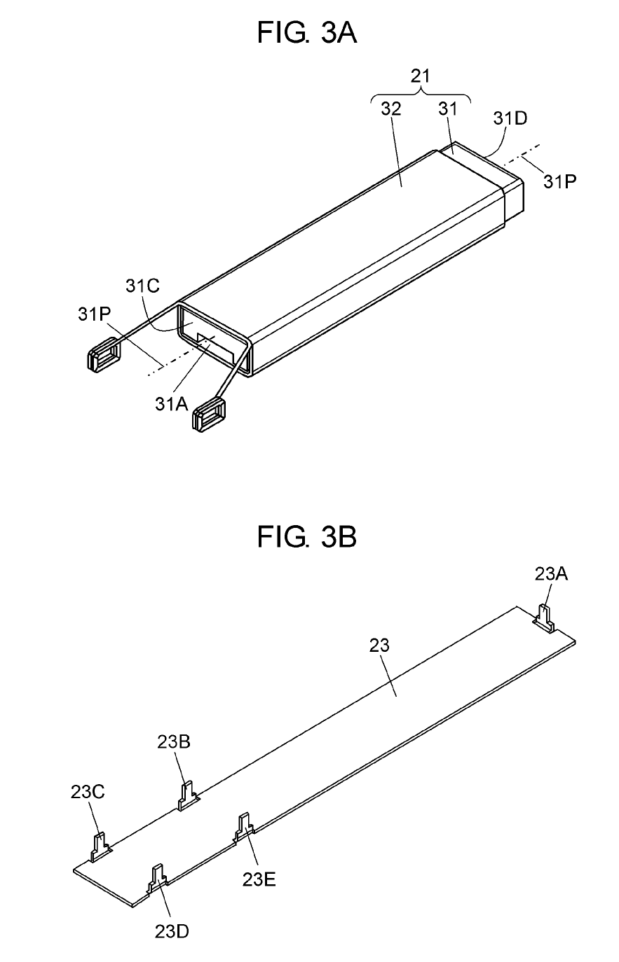

FIG. 3A is a perspective view of antenna section 21. Antenna section 21 includes core 31 made of magnetic material and coil 32 wound around core 31. Core 31 is made of soft magnetic material, such as soft ferrite, iron, or permalloy, and has a rectangular parallelopiped shape. A lower surface of core 31 has groove 31A therein. In detail, core 31 has end surfaces 31C and 31D opposite to each other along center axis 31P, and extends slenderly along center axis 31P. Groove 31A extends from end surface 31C to end surface 31D to pass through core 31. Coil 32 is made of, e.g. a metal wire wound around core 31 about center axis 31P. The metal wire may be made of a polyurethane copper line having a diameter ranging from 0.1 mm to 0.7 mm. In the case that core 31 is made of metal having a small volume resistivity, an insulating tape is preferably wound around core 31 to insulate coil 32 from core 31.

FIG. 3B is a perspective view of sensor electrode 23. Sensor electrode 23 is made of a metal plate having a thickness ranging from 0.1 mm to 0.4 mm and made of, e.g. steel or copper alloy. A surface of sensor electrode 23 may be plated with metal, such as nickel or tin. Sensor electrode 23 has protrusions 23A to 23E bent perpendicularly. Protrusion 23A is provided at the right end of sensor electrode 23. Protrusions 23B to 23E are provided near the left end of sensor electrode 23.

Substrate unit 22 includes substrate 41, resonance circuit 42 mounted onto substrate 41, and sensor circuit 43 mounted onto substrate 41.

FIG. 3C is a perspective view of substrate 41. Substrate 41 includes mounting section 41C having sensor circuit 43 mounted thereto, antenna insertion section 41B extending from end surface 41P of mounting section 41C, and tip end section 41A provided at a distal end of antenna insertion section 41B opposite to mounting section 41C. Antenna insertion section 41B is positioned in antenna section 21. Substrate 41 is preferably made of a rigid substrate, such as a glass epoxy substrate, a paper phenol substrate, or a polytetrafluoroethylene substrate, having a stable shape allowing antenna section 21 to be easily fixed.

Tip end section 41A of substrate 41 is inserted to groove 31A of core 31 of antenna section 21, and protrudes from core 31. Tip end section 41A has fixing hole 41D therein for fixing sensor electrode 23. Protrusion 23A of sensor electrode 23 is inserted in fixing hole 41D and is fixed to tip end section 41A of substrate 41 by, e.g. soldering.

Antenna insertion section 41B of substrate 41 is positioned in groove 31A of core 31 of antenna section 21. Antenna section 21 may be fixed to substrate 41 such that, after coil 32 is wound around core 31, antenna insertion section 41B of substrate 41 is inserted to groove 31A. Alternatively, antenna section 21 may be fixed to substrate 41 such that after antenna insertion section 41B of substrate 41 is inserted to groove 31A, coil 32 is wound around core 31.

Substrate 41 includes two coil lock sections 41E provided at mounting section 41C. Through⁻holes 41F are provided in mounting section 41C. Mounting section 41C has fixing holes 41G to 41J therein for fixing sensor electrode 23. A width of mounting section 41C is larger than that of antenna insertion section 41B. Substrate 41 has step section 41K provided at a portion at which the width changes from mounting section 41C to antenna insertion section 41B. Step section 41K contacts an end of antenna section 21 to easily position antenna section 21 with respect to substrate 41. Specifically, end surface 41P of mounting section 41C has a width larger than that of antenna insertion section 41B to provide step section 41K. End surface 31C of core 31 of antenna section 21 contacts step section 41K of end surface 41P of mounting section 41C.

Two coil lock sections 41E protrude from mounting section 41C near antenna section 21. Both ends of coil 32 are wound and held at coil lock section 41E to connect coil 32 to wiring traces provided on substrate 41. The wiring traces of substrate 41 may be provided on mounting section 41C and are not necessarily provided on tip end section 41A or antenna insertion section 41B.

Through-holes 41F are arranged in a line at an end opposite to tip end section 41A. Through⁻holes 41F are connected to resonance circuit 42 and sensor circuit 43 via wiring traces provided on substrate 41.

Fixing holes 41G to 41J are provided between coil lock section 41E and through-holes 41F. Protrusions 23B to 23E of sensor electrode 23 are inserted to fixing holes 41G to 41J and fixed by, e.g. soldering, respectively.

Resonance circuit 42 provided on mounting section 41C includes capacitor 51 and resistance 52. Capacitor 51 and resistance 52 are connected to coil 32 via wiring traces and coil lock section 41E formed at substrate 41 to form a series resonance circuit.

Sensor electrode 23 is preferably made of a metal plate, such as steel or copper alloy, having a low magnetic permeability. This material suppresses influences of a stray capacitance produced between coil 32 and sensor electrode 23 on the resonance frequency of the series resonance circuit including coil 32 and capacitor 51. More specifically, sensor electrode 23 having a low magnetic permeability can reduce a change in the resonance frequency by about 0.05%, therefore allowing coil 32 to stably generate a predetermined magnetic field strength.

Sensor circuit 43 placed on mounting section 41C includes electronic components, such as an integrated circuit (IC), a resistance, and a capacitor. Sensor circuit 43 is connected to sensor electrode 23 via wiring traces formed on substrate 41 and detects a change in a capacitance of sensor electrode 23.

Only fixing hole 41G out of fixing holes 41D and 41G to 41J is connected to sensor circuit 43 via a wiring trace. Other fixing holes 41D and 41H to 41J are insulated from resonance circuit 42 and sensor circuit 43.

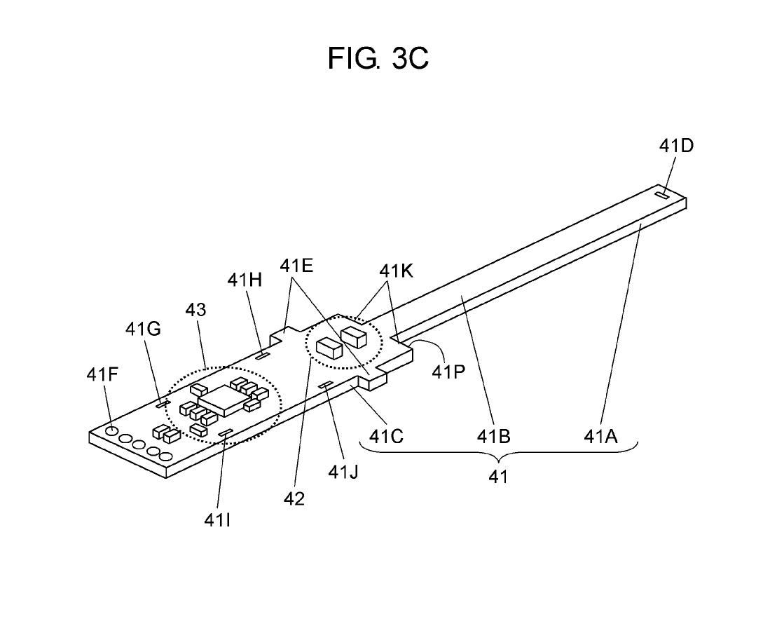

FIG. 4 is a cross-sectional view of antenna device 100 installed in door handle 82 of vehicle 101. Door handle 82 includes handle body 83 having hollow section 82P therein and handle cover 84 covering hollow section 82P. Handle body 83 and handle cover 84 are made of synthetic resin. Antenna device 100 and switch 81 are provided in hollow section 82P of door handle 82.

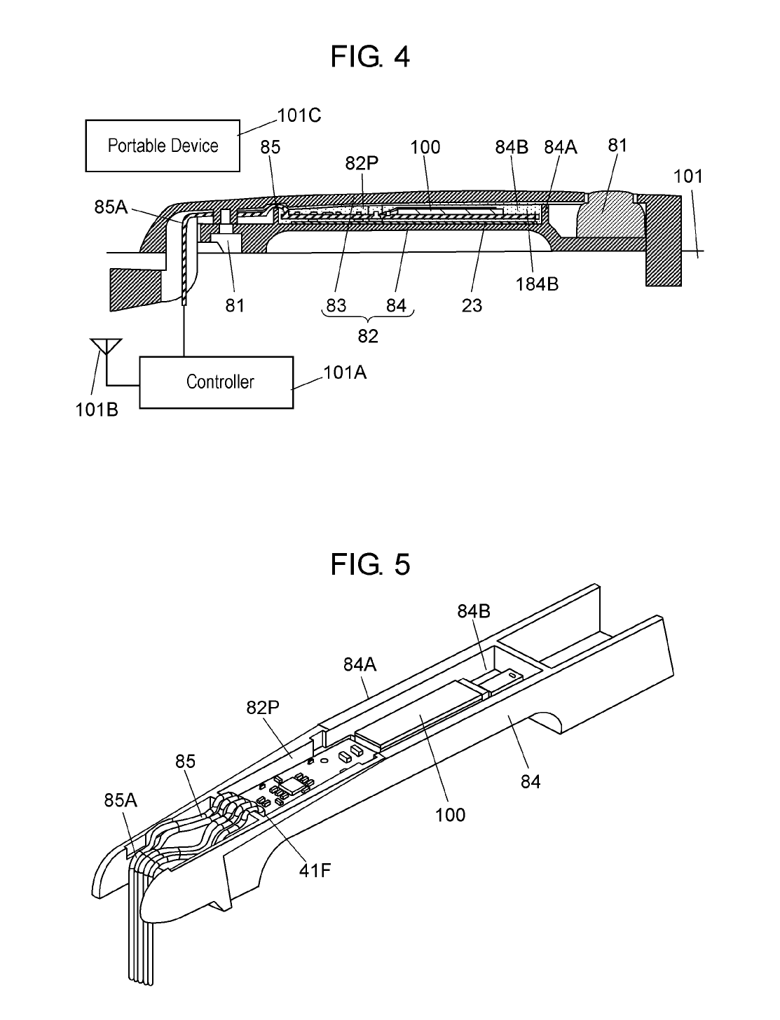

FIG. 5 is a perspective view of antenna device 100 installed in door handle 82 and illustrates the inside of hollow section 82P of door handle 82 with handle cover 84 is removed. Antenna device 100 is accommodated in recess 84B constituted by wall 84A formed at the upper side of handle cover 84. Adhesive agent or a double-surface adhesive tape is used to fix sensor electrode 23 to a bottom of recess 84B.

Wirings 85A of harness 85 are inserted to through-holes 41F, respectively, and are fixed by, e.g. soldering. Harness 85 extends from recess 84B and is connected to controller 101A of vehicle 101. One or both of capacitor 51 and resistance 52 of resonance circuit 42 may be connected to controller 101A of vehicle 101. Recess 84B is filled with seal material 184B, such as a urethane resin or silicone resin. Antenna device 100 is entirely covered with seal material 184B. Seal material 184B provides antenna device 100 with the waterproof property within door handle 82.

An operation of antenna device 100 will be described below.

When a user carrying portable device 101C shown in FIG. 4 touches door handle 82, controller 101A connected to antenna device 100 detects a change of a capacitance of sensor electrode 23. Then, controller 101A sends a request signal having a predetermined frequency via antenna device 100.

Upon receiving the request signal, portable device 101C sends a response signal to vehicle 101.

Upon receiving the response signal via receiving antenna 101B, controller 101A of vehicle 101 confirms the response signal and unlocks a door of vehicle 101. When the user carrying portable device 101C is removed away from vehicle 101, the user operates switch 81 provided in door handle 82 to lock the door of vehicle 101.

Antenna device 100 is configured such that the resonance frequency can be adjusted by changing the size of core 31 or the number of turns of coil 32. This configuration does not require the change of the configuration of substrate 41 even if the shape of door handle 82 changes and require the adjustment of the resonance frequency. As described above, in antenna device 100, core 31 and coil 32 can be easily changed. Antenna device 100 can be accommodated in door handles 82 of various shapes, thus being usable in various types of vehicles.

Sensor electrode 23 may easily change its capacitance by providing a slit or having a different width or length. Thus, sensor circuit 43 of antenna device 100 can detect the touch of door handle 82 by the user with a desired sensitivity.

Antenna device 100 has a waterproof property provided by seal material 184B. Antenna device 100 may be located in recess 84B that is entirely molded by synthetic resin, such as urethane resin, thereby providing the waterproof property.

Instead of through-holes 41F, antenna device 100 may include connection terminals or a connector provided on mounting section 41C of substrate 41 and electrically connected to harness 85. The connection terminals or the connector include metal terminals.

Sensor electrode 23 may be electrically connected to substrate 41 by other methods, such as alloy connection or melting connection, besides soldering.

In antenna device 100, substrate 41 is inserted to groove 31A provided in the lower surface of core 31. Instead of groove 31A, substrate 41 may be inserted to a through-hole provided in core 31.

Antenna device 100 may be used as an antenna device that is provided not in door handle 82 of vehicle 101 but in a door of a house, to lock and unlock the door.

As described above, antenna device 100 according to Embodiment 1 includes sensor electrode 23 having a capacitance that changes upon an object approaching or contacting sensor electrode 23, sensor circuit 43 for detecting the capacitance of sensor electrode 23, antenna section 21 including coil 32 and core 31, and substrate 41. Substrate 41 has sensor circuit 43 and sensor electrode 23 thereon, and is inserted into antenna section 21. This configuration allows substrate 41 to penetrate through antenna section 21 while providing an integrated structure of sensor electrode 23, sensor circuit 43, antenna section 21, and substrate 41, thus easily positioning antenna section 21.

Substrate 41 includes tip end section 41A, antenna insertion section 41B, and mounting section 41C. Mounting section 41C has a width larger than that of antenna insertion section 41B, providing step section 41K. Step section 41K contacts antenna section 21. Step section 41K contacting antenna section 21 can easily positions antenna section 21 with respect to substrate 41, and allows antenna device 100 to resist to vibration.

### Exemplary Embodiment 2

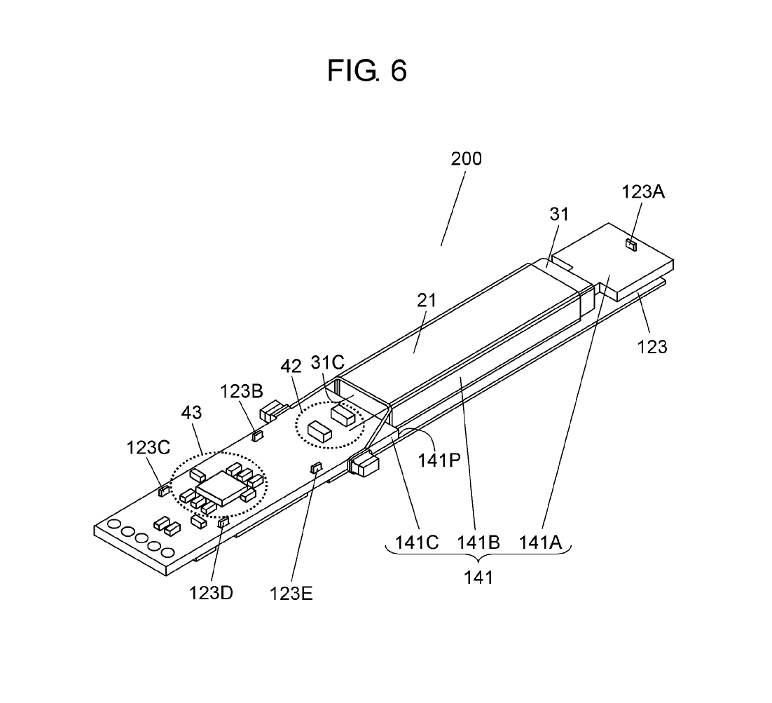

FIG. 6 is a perspective view of antenna device 200 according to Exemplary Embodiment 2 of the present invention. In FIG. 6, components identical to those of antenna device 100 according to Embodiment 1 shown in FIGS. 1A to 5 are denoted by the same reference numerals. Antenna device 200 according to Embodiment 2 includes sensor electrode 123 and substrate 141 instead of sensor electrode 23 and substrate 41 of antenna device 100 according to Embodiment 1 shown in FIGS. 1A to 5.

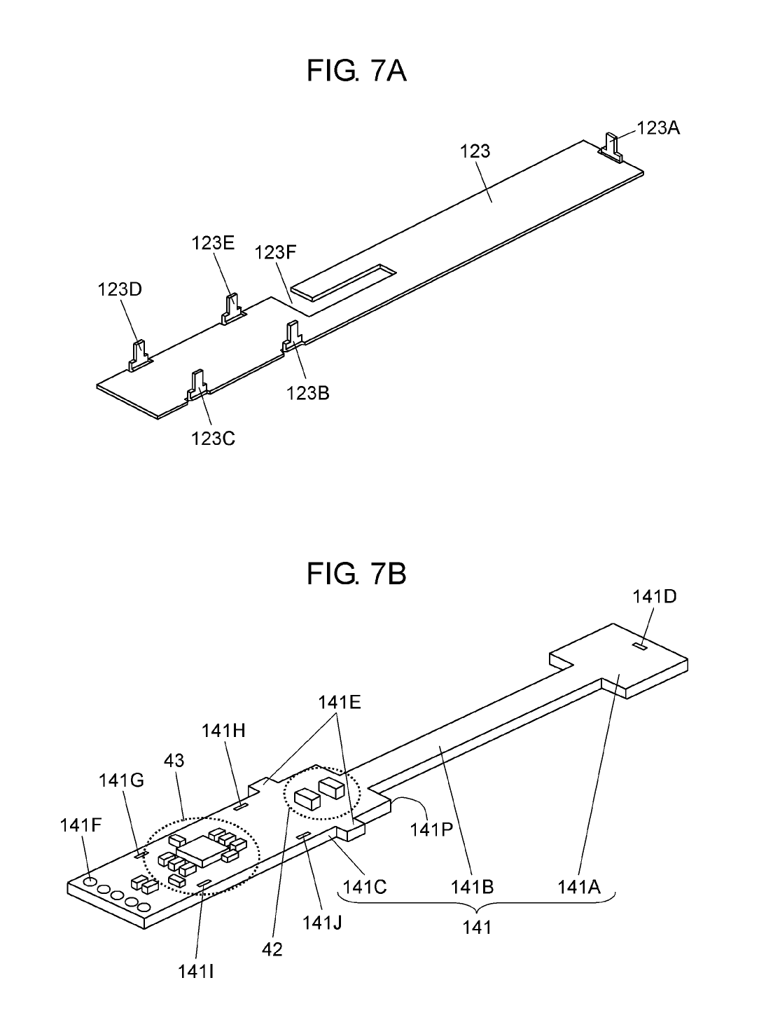

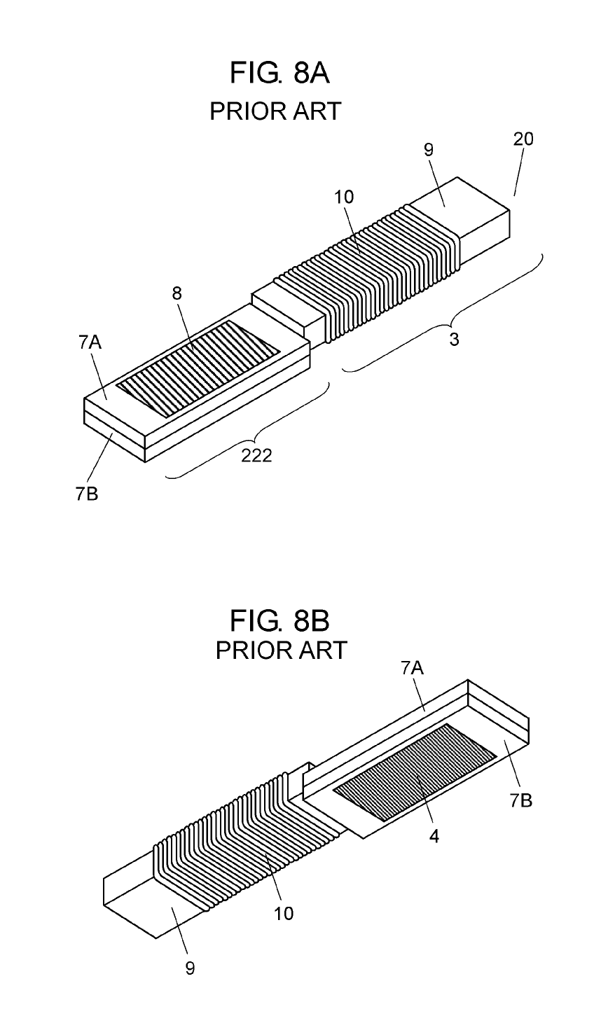

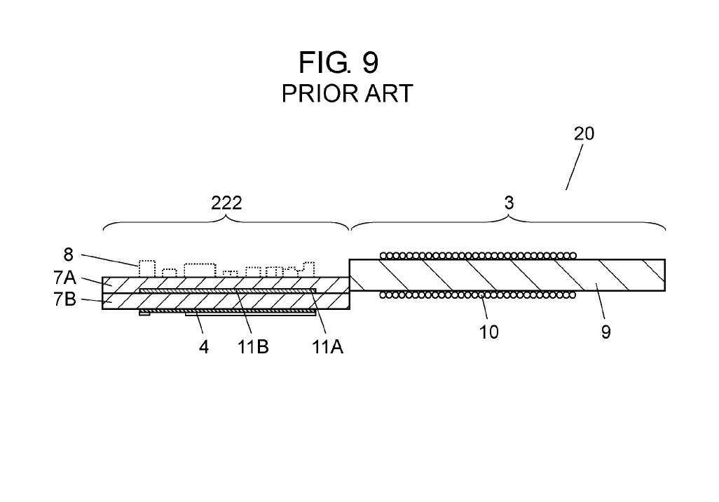

FIG. 7A is a perspective view of sensor electrode 123. Sensor electrode 123 is made of a metal plate similar to sensor electrode 23 according to Embodiment 1. Sensor electrode 123 has protrusions 123A to 123E bent perpendicularly similar to protrusions 23A to 23E of sensor electrode 23 according to Embodiment 1. Protrusion 123A is provided at the right end of sensor electrode 123. Protrusions 123B, 123C, 123D, and 123E are provided at the left end of sensor electrode 123. Slit 123F is provided in sensor electrode 123 between protrusions 123A and 123E.

FIG. 7B is a perspective view of substrate 141. Substrate 141 includes mounting section 141C having sensor circuit 43 mounted thereon, antenna insertion section 141B extending from end surface 141P of mounting section 141C, and tip end section 141A provided at an end of antenna insertion section 141B opposite to mounting section 141C. Antenna insertion section 141B is positioned in antenna section 21.

In substrate 141, antenna insertion section 141B has a width smaller than a width of tip end section 141A and a width of mounting section 141C. End section 141A and mounting section 141C are connected to both ends of antenna insertion section 141B. Tip end section 141A has a width substantially equal to that of mounting section 141C.

Tip end section 141A protrudes from core 31 while antenna insertion section 141B of substrate 141 is inserted into groove 31A. Fixing hole 141D is provided in an tip end of tip end section 141A. The tip end of protrusion 123A is inserted to fixing hole 141D and is fixed by, e.g. soldering.

Antenna insertion section 141B is inserted into groove 31A. Antenna insertion section 141B of substrate 141 is inserted into groove 31A, and then coil 32 is wound round core 31, thereby fixing antenna section 21 to substrate 141.

Mounting section 141C includes coil lock section 141E. Through-hole 141F and fixing holes 141G to 141J are provided in mounting section 141C. Antenna section 21 is provided between tip end section 141A and mounting section 141C. Antenna insertion section 141B is inserted into groove 31A. Antenna section 21 is sandwiched between tip end section 141A and mounting section 141C. Thus, antenna section 21 can be easily positioned with respect to substrate 141 and can endure vibration.

Mounting section 141C has resonance circuit 42 and sensor circuit 43 mounted thereon.

Resonance circuit 42 is connected to coil 32 via wiring traces and coil lock section 141E formed at substrate 141.

Sensor circuit 43 is connected to sensor electrode 123 via wiring traces formed on substrate 141 and is configure to detect a change of a capacitance of sensor electrode 123.

Fixing hole 141G out of fixing holes 141G to 141J is connected to protrusion 123D functioning as a ground protrusion. Fixing hole 141H is connected to protrusion 123E functioning as a circuit connection protrusion. Circuit connection protrusion 123E is connected to sensor circuit 43 via fixing hole 141H. Sensor circuit 43 is configured to detect the capacitance. Ground protrusion 123D is connected to a ground of sensor circuit 43 via fixing hole 141G.

The sensitivity of the detecting of the capacitance can be adjusted by adjusting the shape of slit 123F or the position of ground protrusion 123D. For example, the sensitivity of the detecting of the capacitance can be significantly changed by changing the width or length of slit 123F. The sensitivity of the detecting of the capacitance can be slightly adjusted by moving the position of ground protrusion 123D toward or away from circuit connection protrusion 123E. This operation can suppress variations of the capacitance, and provides higher detection accuracy.

Substrate 141 may have a transmitting circuit or a receiving circuit mounted thereon, and the circuit is connected to sensor electrode 123 so that sensor electrode 123 may function as an antenna. In this case, a communication frequency of sensor electrode 123 is higher than a frequency at which the communication via antenna section 21.

In antenna device 200 according to Embodiment 2, substrate 141 includes tip end section 141A, antenna insertion section 141B, and mounting section 141C. antenna section 21 is provided between tip end section 141A and mounting section 141C. This configuration restricts a backlash of antenna section 21, providing antenna device 200 with more durability against vibration.

Sensor electrode 123 includes ground protrusion 123D and circuit connection protrusion 123E. Ground protrusion 123D is connected to the ground of sensor circuit 43. Sensor circuit 4 is configured to detect the capacitance based on a signal input through circuit connection protrusion 123E. This configuration allows the capacitance detection sensitivity to be adjusted by changing the position of ground protrusion 123D.

Sensor electrode 123 has slit 123F therein. The capacitance detection sensitivity can be adjusted by changing the shape of slit 123F.

Antenna devices 100 and 200 according to Embodiments 1 and 2 allows the components to be easily positioned during manufacturing, and is useful for locking and unlocking a door of, e.g. a vehicle or a house.

What is claimed is:

1. An antenna device comprising:
a sensor electrode having a capacitance configured to change upon an object approaching or contacting the sensor electrode;
a sensor circuit electrically connected to the sensor electrode, the sensor circuit being configured to detect the capacitance;
an antenna section including a core and a coil wound around the core; and
a substrate having the sensor circuit mounted thereon and having the sensor electrode fixed thereto, the substrate being inserted into the antenna section.

2. The antenna device according to claim 1,
wherein the substrate includes:
a mounting section having the sensor circuit mounted thereon; and
an antenna insertion section extending from an end surface of the mounting section to an inside of the antenna section,
wherein the end surface of the mounting section has a width larger than a width of the antenna insertion section to provide a step section, and
wherein the antenna section contacts the step section of the end surface of the mounting section.

3. The antenna device according to claim 1,
wherein the substrate includes:
a mounting section having the sensor circuit mounted thereon;
an antenna insertion section extending from an end surface of the mounting section to an inside of the antenna section; and
a tip end provided at an end of the antenna insertion section opposite to the mounting section, and
wherein the antenna section is provided between the tip end section and the mounting section.

4. The antenna device according to claim 1,
wherein the sensor electrode has a circuit connection protrusion and a ground protrusion connected to a ground of the sensor circuit, and
wherein the sensor circuit is configured to detect the capacitance based on a signal input through the circuit connection protrusion.

5. The antenna device according to claim 1, wherein the sensor electrode has a slit therein.
